(19) United States
(12) Patent Application Publication
(10) Pub. No.: US 2025/0234597 A1
(43) Pub. Date: Jul. 17, 2025

(54) THIN FILM TRANSISTOR AND METHOD FOR MANUFACTURING SAME, AND METHOD FOR MANUFACTURING DISPLAY SUBSTRATE

(71) Applicants: Hefei Xinsheng Optoelectronics Technology Co., Ltd., Hefei, Anhui (CN); BOE Technology Group Co., Ltd., Beijing (CN); Beijing BOE Technology Development Co., Ltd., Beijing (CN)

(72) Inventors: Zhangtao WANG, Beijing (CN); Ran ZHANG, Beijing (CN); Zhixiang ZOU, Beijing (CN); Liang LIN, Beijing (CN)

(21) Appl. No.: 18/700,657

(22) PCT Filed: Apr. 28, 2023
(86) PCT No.: PCT/CN2023/091512

§ 371 Date: Apr. 11, 2024

(51) Int. Cl. H10D 30/67; H10D 30/01; H10D 86/01

(52) U.S. Cl. CPC H10D 30/6756; H10D 30/031; H10D 86/0221

(57) ABSTRACT

Provided is a thin film transistor. The thin film transistor includes a base substrate and an active layer disposed on the base substrate, the active layer includes a first film layer and a second film layer sequentially laminated in a direction away from the base substrate; wherein a material of the active layer is a metal oxide comprising an indium element and a gallium element, an indium element content in the first film layer is In1, and an indium element content in the second film layer is In2, where 0≤[|In1-In2|/max(In1, In2)]≤0.5; the first film layer and the second film layer are in an amorphous state, and a mobility of a material of the first film layer is greater than a mobility of a material of the second film layer.

### CROSS-REFERENCE TO RELATED APPLICATION

This application is a U.S. national stage of international application No. PCT/CN2023/091512, filed on Apr. 28, 2023, the disclosure of which is herein incorporated by reference in its entirety.

### TECHNICAL FIELD

The present disclosure relates to the field of display technology, and in particular, relates to a thin film transistor and a method for manufacturing the same, and a method for manufacturing a display substrate.

### BACKGROUND

Mobility refers to the moving speed of electrons in a semiconductor material, and for semiconductor display devices, the mobility represents the display quality and the service life that the semiconductor display devices having the same size can achieve. In the prior art, the effective mobilities of amorphous silicon (a-Si), metal oxide and low temperature poly-silicon (LTPS) used in the industry are actually about 1 cm²/V*s, 10 cm²/V*s and 80 cm²/V*s, respectively. It can be seen that the material capability of LTPS is far ahead.

### SUMMARY

Some embodiments of the present disclosure provide a thin film transistor. The thin film transistor includes: a base substrate and an active layer disposed on the base substrate, the active layer including a first film layer and a second film layer sequentially laminated in a direction away from the base substrate; wherein
a material of the active layer is a metal oxide including an indium element and a gallium element, wherein an indium element content in the first film layer is In1, and an indium element content in the second film layer is In2, where 0≤[|In1-In2/max(In1, In2)]≤0.5; the first film layer and the second film layer are in an amorphous state, and a mobility of a material of the first film layer is greater than a mobility of a material of the second film layer.

In some embodiments, a ratio of a thickness of the second film layer to a thickness of the first film layer ranges from 1 to 10.

In some embodiments, the thin film transistor further includes: a gate layer, and a gate insulating layer disposed between the gate layer and the active layer; wherein the first film layer is closer to the gate layer than the second film layer is, the thickness of the first film layer ranges from 5 nm to 25 nm, and the thickness of the second film layer ranges from 40 nm to 120 nm.

In some embodiments, the thin film transistor further includes: a gate layer, and a gate insulating layer disposed between the gate layer and the active layer; wherein the second film layer is closer to the gate layer than the first film layer is, the thickness of the first film layer ranges from 10 nm to 20 nm, and the thickness of the second film layer ranges from 10 nm to 50 nm.

In some embodiments, a gallium element content in the first film layer is Ga1, and a gallium element content in the second film layer is Ga2, where Ga1>Ga2, and 1<Ga1/Ga2≤4.

In some embodiments, the active layer further includes a zinc element, a zinc element content in the first film layer is Zn1, and a zinc element content in the second film layer is Zn2, where Zn1>Zn2, and 1≤Zn1/Zn2≤2.

In some embodiments, the active layer further includes a tin element, a tin element content in the first film layer is T1, and a tin element content in the second film layer is T2, where T1>T2≥0.

In some embodiments, a ratio range of the indium element content to the gallium element content in the first film layer is 2≤In1/Ga1≤5.

In some embodiments, a ratio range of the indium element content to the gallium element content in the second film layer is 0≤In2/Ga2≤2.

In some embodiments, a ratio range of the zinc element content to the gallium element content in the first film layer is 3≤Zn1/Ga1≤5.

In some embodiments, a ratio range of the zinc element content to the gallium element content in the second film layer is 0≤Zn2/Ga2≤2.

In some embodiments, a ratio range of the indium element content to the tin element content in the first film layer is 3≤In1/T1≤5.

In some embodiments, a threshold voltage of the thin film transistor ranges from 1 V to 2 V.

In some embodiments, an electron mobility of the thin film transistor ranges from 17 cm²/V*s to 24 cm²/V*s.

In some embodiments, a positive shift of the threshold voltage of the thin film transistor is less than 3 V under an action of a positive bias temperature stress.

In some embodiments, a negative shift of the threshold voltage of the thin film transistor is less than 4 V under an action of a negative bias temperature illumination stress.

In some embodiments, a withstand voltage between a source and a drain of the thin film transistor is not less than 63 V.

Some embodiments of the present disclosure further provide a method for manufacturing a thin film transistor. The method includes:
providing a base substrate; and
forming an active layer; wherein forming the active layer includes: forming a first film layer and a second film layer that are sequentially laminated along a direction away from the base substrate; wherein a material of the active layer is a metal oxide including an indium element and a gallium element, wherein an indium element content in the first film layer is In1, and an indium element content in the second film layer is In2, where 0≤[|In1-In2|/max(In1, In2)]≤0.5; the first film layer and the second film layer are in an amorphous state, and a mobility of a material of the first film layer is greater than a mobility of a material of the second film layer.

In some embodiments, the material of the second film layer is indium gallium zinc oxide, and an atomic ratio in indium gallium zinc oxide is In:Ga:Zn=1:1:1.

In some embodiments, the method for manufacturing the thin film transistor further includes:
forming a gate layer and a gate insulating layer sequentially on the base substrate prior to forming the active layer; and
forming a source layer and a drain layer upon forming the active layer, wherein the source layer and the drain layer are electrically connected to a source contact region and a drain contact region of the active layer, respectively.

In some embodiments, the material of the first film layer is indium gallium zinc tin oxide, and a thickness of the first film layer ranges from 5 nm to 25 nm; and a thickness of the second film layer ranges from 40 nm to 120 nm.

In some embodiments, the method for manufacturing the thin film transistor further includes:
forming a light shielding layer and a buffer layer sequentially on the base substrate prior to forming the active layer; and
forming a gate layer, a gate insulating layer, an interlayer insulating layer, a source layer and a drain layer upon forming the active layer, wherein the source layer and the drain layer are electrically connected to a source contact region and a drain contact region of the active layer, respectively.

In some embodiments, the material of the first film layer is indium gallium zinc tin oxide or indium gallium oxide, and a thickness of the first film layer ranges from 10 nm to 20 nm; and a thickness of the second film layer ranges from 10 nm to 50 nm.

Some embodiments of the present disclosure further provide a method for manufacturing a display substrate, wherein the display substrate includes the thin film transistor manufactured by the method for manufacturing the thin film transistor as defined in any one of the above embodiments.

In some embodiments, the method for manufacturing the display substrate further includes:
forming a first passivation layer, wherein the first passivation layer is disposed on a side of the source layer and a side of the drain layer that are away from the base substrate;
forming a planarization layer, wherein the planarization layer is disposed on a side of the first passivation layer away from the base substrate;
forming a first electrode layer, wherein the first electrode layer is disposed on a side of the planarization layer away from the base substrate, and a material of the first electrode layer is a transparent conductive material;
forming a second passivation layer, wherein the second passivation layer is disposed on a side of the first electrode layer away from the base substrate;
forming a second electrode layer, wherein the second electrode layer is disposed on a side of the second passivation layer away from the base substrate, and the second electrode layer is connected to the source layer through a via hole penetrating through the second passivation layer.

### BRIEF DESCRIPTION OF DRAWINGS

FIG. 1 is a schematic structural diagram of a thin film transistor according to some embodiments of the present disclosure;

FIG. 2 is a schematic structural diagram of another thin film transistor according to some embodiments of the present disclosure;

FIG. 3a to FIG. 3j are flow diagrams of a manufacturing process of a bottom-gate metal oxide thin film transistor according to some embodiments of the present disclosure;

FIG. 4a is a schematic diagram of a transmission electron bright field image for a device section of a bottom-gate metal oxide thin film transistor according to some embodiments of the present disclosure;

FIG. 4b is a schematic diagram of a scattered electron dark field image for a bottom-gate metal oxide thin film transistor according to some embodiments of the present disclosure;

FIG. 4c is an energy spectrum diagram of elements of an active layer of a bottom-gate metal oxide thin film transistor according to some embodiments of the present disclosure;

FIG. 5 is a schematic diagram showing device characteristics of a bottom-gate metal oxide thin film transistor according to some embodiments of the present disclosure;

FIG. 6 is a test diagram of withstand voltage Vds capability of a bottom-gate metal oxide thin film transistor according to some embodiments of the present disclosure;

FIG. 7 is a schematic diagram showing a change of the device characteristics with the thickness of a first film layer of a bottom-gate metal oxide thin film transistor according to some embodiments of the present disclosure;

FIG. 8 is a schematic diagram showing a change of the device characteristics with the thickness of a second film layer of a bottom-gate metal oxide thin film transistor according to some embodiments of the present disclosure; and

FIG. 9a to FIG. 9m are flow diagrams of a manufacturing process of a top-gate metal oxide thin film transistor according to some embodiments of the present disclosure.

Reference numerals in the accompanying drawings: 10—base substrate; 20—gate layer; 30—gate insulating layer; 40—active layer; 41—first film layer; 42—second film layer; 51—source layer; 52—drain layer; 61—first passivation layer; 70—planarization layer; 81—first electrode layer; 62—second passivation layer; 82—second electrode layer; 11—light shielding layer; 12—buffer layer; 90—interlayer insulating layer.

### DETAILED DESCRIPTION

In order to make the objectives, technical solutions and advantages of the embodiments of the present disclosure clearer, the technical solutions in the embodiments of the present disclosure are described clearly and completely hereinafter with reference to the accompanying drawings. The embodiments described are merely some embodiments rather than all embodiments of the present disclosure. Generally, in the embodiments of the present disclosure, the components described and illustrated in the drawings may be arranged and designed in a variety of different configurations. Accordingly, the following detailed descriptions of the embodiments of the present disclosure provided in the accompanying drawings are not intended to limit the scope of the claimed disclosure, but merely represent selected embodiments of the present disclosure. On the basis of the embodiments of the present disclosure, all other embodiments derived by those skilled in the art without creative effort shall fall within the scope of the present disclosure.

Unless otherwise defined, the technical or scientific terms used in the present disclosure shall have the ordinary meaning understood by a person of ordinary skill in the art to which the present disclosure pertains. The terms “first,” “second,” and the like, as used in the present do not indicate any order, quantity, or importance, but are used only to distinguish between different components. Similarly, words such as “one,” “a/an,” and “the” and similar words do not indicate a limitation in quantity, but rather indicate the presence of at least one. Words such as “include” and “comprise” and similar words mean that the element or object appearing ahead of the word encompasses the element(s) or object(s) listed after the word and equivalents thereof, without excluding other elements or objects. Words such as “connect” and “couple” and similar words are not limited to physical or mechanical connections, but may include electrical connections, whether direct or indirect. Words such as “on,” “under,” “left,” and “right” are used only to indicate relative positional relationships. When the absolute position of the described object is changed, the relative positional relationship may be changed accordingly.

In the present disclosure, “a plurality of or several” refers to two or more. The character “and/or” describes an association relationship of the associated objects and indicates that three relationships may exist. For example, A and/or B may be expressed as: A exits alone, A and B exit concurrently, and B exits alone. The character “/” generally indicates an “or” relationship between the associated objects.

With the development of science and technology, human society has entered the information age, and more and more information is acquired by people through a screen. Mobile phones, computers and television screens commonly used by people all belong to flat panel display (FPD). Nowadays, FPDs are developing toward high resolution, lightness and thinness, flexibility, and energy-saving. As a switch control element or an integrated component of a peripheral drive circuit, the thin film transistor (TFT) a is a core device in the display technology, and the electrical performance of the thin film transistor determines the quality of the display device.

TFTs belong to field-effect transistors in classification, and the TFT consists of a gate electrode, a gate insulating layer, a channel layer and a source/drain electrode, and the material and manufacturing process of each part are crucial to the performance of the whole device. Conventional amorphous silicon thin film transistors (a-Si: H TFT) were widely used in industrial production because of their advantages of light weight, small volume and the like. However, due to the disadvantage of the low carrier mobility, the amorphous silicon thin film transistors cannot follow the development trend of high definition and large screen of today's display devices, and can only be applied to the field of small display devices. The LTPS TFTs have a high carrier mobility, but the mobility distribution uniformity is poor due to the high preparation temperature, complex production process, high production costs, and grain boundaries. As a result, the LTPS TFTs are not suitable for large-area production. In addition, a-Si: H TFTs and LTPS TFTs have a very low optical transmittance in the visible light range and cannot be bent, which limits the development of transparent display and flexible display. Oxide thin film transistors (oxide TFTs) have been widely studied in recent years because they are flexible, suitable for large-area production and simple in processes, and the carrier mobility of oxide TFTs has exceeded the carrier mobility of a-Si TFTs.

The inventors found that in order to improve the mobility of the metal oxide, different series of materials are developed for the metal oxide thin film transistors in the prior art, and the proportion of the elements in the metal oxide is adjusted. However, as the mobility of metal oxide materials is increased, some problems also arise.

For example, the optical band gap of the high mobility material is reduced, that is, electrons in the high mobility materials absorb part of the light in the visible light band to generate an electron transition, which is reflected in the device capability as that the TFT is turned on in advance in case of light. Moreover, the newly-added defects under illumination are increased, and the negative bias temperature illumination stress characteristic is seriously deteriorated, which is reflected as serious service life degradation. In addition, the metal oxide thin film transistors made of the high mobility materials have a high electron drift velocity and high current density, and the local heat is rapidly released, resulting in local high temperature of the TFT device, which accelerates the characteristic deterioration, and even causes a burning phenomenon.

It should be noted that the metal oxide thin film transistors are sensitive to voltage stress, temperature and illumination, which seriously affects their characteristics. Specifically, the metal oxide thin film transistors are usually subjected to the following two common stresses: positive bias temperature stress (PBTS) and negative bias temperature illumination stress (NBTIS). Generally, the thin film transistor shifts positively under the action of the PBTS and shifts negatively under the action of the NBTIS. In this way, the reliability of the threshold voltage Vth of the thin film transistor can be ensured for a long time under the combined action of the PBTS and the NBTIS, that is, in the long-term use, the threshold voltage is neutralized after the positive shift and negative shift, and keeps stable, thereby ensuring the product quality.

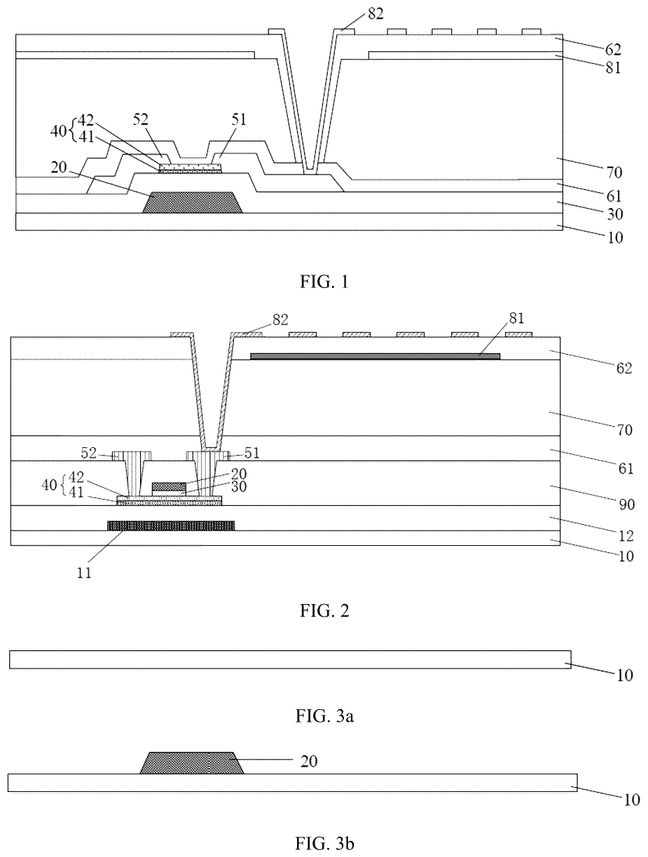

In view of the above, the embodiments of the present disclosure provide a thin film transistor. FIG. 1 is a schematic structural diagram of a thin film transistor according to some embodiments of the present disclosure. As shown in FIG. 1, the thin film transistor in the embodiments of the present disclosure is a metal oxide thin film transistor, which has a dual active laminated structure and is made of a high mobility metal oxide material, which can solve the problems of high electric leakage and high current density which may result in burning of the existing high mobility devices. In this way, the switching capability of the display backplane can be increased and the service life of the product can be prolonged.

It should be noted that the mobility of the high mobility metal oxide material mentioned in the embodiments of the present disclosure is not less than 20 cm²/V*s.

Some embodiments provide a thin film transistor. As shown in FIG. 1, the thin film transistor includes a base substrate 10 and an active layer 40 disposed on the base substrate 10. The active layer 40 includes a first film layer 41 and a second film layer 42 sequentially laminated along a direction away from the base substrate 10. The active layer 40 is made of a metal oxide including an indium element and a gallium element. The indium element content in the first film layer 41 is In1, and the indium element content in the second film layer 42 is In2, where 0≤[|In1-In2|/max(In1, In2)]≤0.5. The first film layer 41 and the second film layer 42 are in an amorphous state, and the mobility of the material of the first film layer 41 is greater than the mobility of the material of the second film layer 42.

Specifically, in the embodiments of the present disclosure, the material of the first film layer 41 of the active layer 40 is a high mobility metal oxide, for example, the material of the first film layer 41 includes, but is not limited to, indium gallium zinc oxide (IGZO), indium gallium oxide (IGO), indium tin zinc oxide (ITZO), indium gallium zinc tin oxide (IGZTO), lanthanide doped metal oxide (Ln-OS), and the like. Since the mobility of the material of the first film layer 41 is not less than the mobility of the material of the second film layer 42, and the mobility of the material of the first film layer 41 is not less than 20 cm²/V*s, an excessive increase of photogenerated defects can be avoided, and the problems of high electric leakage and high current density which result in burning of the display device can be alleviated.

It should be noted that the element content in the present disclosure refers to the mass percentage or atomic percentage of the element, which refers to the element proportion of the element in the entire film layer or the element proportion in a specific film layer, which is not specifically limited in the present disclosure.

It should be noted that |In1-In2| represents an absolute value of the difference between the indium element content in the first film layer 41 and the indium element content in the second film layer 42, and max (In1, In2) represents a greater value of the value of the indium element content in the first film layer 41 and the value of the indium element content in the second film layer 42. When the values of In1 and In2 are equal, the ratio is 0. In general, the difference between In1 and In2 does not exceed 3. Preferably, 0.05≤[|In1-In2|/max(In1, In2)]≤0.25.

In some embodiments, the gallium element content in the first film layer 41 is Ga1, and the gallium element content in the second film layer 42 is Ga2, where Ga1>Ga2, and 1≤Ga1/Ga2≤4.

In some embodiments, the active layer 40 further includes a zinc element, the zinc element content in the first film layer 41 is Zn1, and the zinc element content in the second film layer 42 is Zn2, where Zn1>Zn2, and 1≤Zn1/Zn2≤2.

In some embodiments, the active layer 40 further includes a tin element, the tin element content in the first film layer 41 is T1, and the tin element content in the second film layer 42 is T2, where T1>T2≥0.

In some embodiments, the ratio range of the indium element content to the gallium element content in the first film layer 41 is 2≤In1/Ga1≤5.

In some embodiments, the ratio range of the indium element content to the gallium element content in the second film layer 42 is 0≤In2/Ga2≤2.

In some embodiments, the ratio range of the zinc element content to the gallium element content in the first film layer 41 is 3≤Zn1/Ga1≤5.

In some embodiments, the ratio range of the zinc element content to the gallium element content in the second film layer 42 is 0≤Zn2/Ga2≤2.

In some embodiments, the ratio range of the indium element content to the tin element content in the first film layer 41 is 3≤In1/T1≤5.

The following specific descriptions are provided by taking an example in which the material of the second film layer 42 is IGZO, and the atomic ratio in IGZO is In:Ga:Zn=1:1:1.

Specifically, in the embodiments of the present disclosure, the material of the first film layer 41 of the thin film transistor is a high mobility metal oxide, the material of the second film layer 42 is IGZO, and the atomic ratio in IGZO is In:Ga:Zn=1:1:1. The second film layer 42 is made of IGZO, so as to take advantages of the stability, balanced mobility and resistance of IGZO. The mobility of IGZO is about 10 cm²/V*s, and such an intermediate mobility level can provide certain carriers, so as to compensate for the weak device switching capability caused by the first film layer 41 (i.e., the high mobility layer). Moreover, the intermediate resistance level of IGZO can limit the movement of the carriers of the high mobility layer to a certain extent to control the device to be in a reasonable off-state current level, and the phenomenon that the device overheats and burns due to the high resistance of the device is avoided.

The thin film transistor provided in the embodiments of the present disclosure can alleviate the problems of high electric leakage and large current density resulting in burning of the display device. Therefore, the thin film transistor provided in the embodiments of the present disclosure is applicable to large-sized products, such as display (MNT) products of televisions (TV) and desktop televisions, and scenarios with a large cross voltage.

It should be noted that in the embodiments of the present disclosure, the material of the second film layer 42 includes, but is not limited to, IGZO, that is, materials having a property very close to the property of IGZO may also be used to manufacture the second film layer 42, as long as the second film layer 42 can have the same functions as the first film layer 41 with the high mobility, i.e., the functions of alleviating the problems of high electric leakage and large current density resulting in burning of the thin film transistor, and thus increasing the switching capability of the display backplane and prolonging the service life of the product.

In some embodiments, as shown in FIG. 1, the thin film transistor further includes a gate layer 20, and a gate insulating layer 30 disposed between the gate layer 20 and the active layer 40. The gate insulating layer 30 is configured to isolate the gate layer 20 from the active layer 40, thereby avoiding a short circuit.

It should be noted that the structures of the thin film transistors are simply divided into a bottom-gate structure and a top-gate structure according to the positional relationship between the gate layer 20 and the active layer 40. In the top-gate structure, the gate is disposed at the top of the device, and in the bottom-gate structure, the gate is disposed on the base. In the manufacturing process, regardless of how to design a new structure, the device consists of common components: a base, a gate (i.e., gate layer 20), an insulating layer (i.e., gate insulating layer 30), an active layer 40, a source/drain electrode, and the like. There are different device structures according to the relative position of different components of the device. In the embodiments of the present disclosure, the thin film transistor shown in FIG. 1 is a bottom-gate thin film transistor. FIG. 2 is a schematic structural diagram of another thin film transistor according to some embodiments of the present disclosure. As shown in FIG. 2, the thin film transistor is a top-gate thin film transistor

It should be noted that the active layer 40 of the thin film transistor in the present disclosure is a dual active laminated structure, and is applicable to thin film transistors of different structures. For ease of description and understanding, the embodiments of the present disclosure are mainly described in detail with respect to the bottom-gate thin film transistor and the top-gate thin film transistor.

It should be noted that the ratio of the thickness of the second film layer 42 to the thickness of the first film layer 41 in the active layer 40 ranges from 1 to 10, no matter whether the thin film transistor is a bottom-gate thin film transistor or a top-gate thin film transistor. For the thin film transistor provided in the embodiments of the present disclosure, by adjusting the range of the ratio of the thickness of the second film layer 42 to the thickness of the first film layer 41 in the active layer 40, it is ensured that the first film layer 41 and the second film layer 42 can be formed completely while ensuring that the thin film transistor reaches the preset mobility, thereby reducing film layer defects.

In some embodiments, as shown in FIG. 1, the first film layer 41 is closer to the gate layer 20 than the second film layer 42 is, that is, the thin film transistor is a bottom-gate thin film transistor. The first film layer 41 is made of IGZTO, and the thickness of the first film layer 41 ranges from 5 nm to 25 nm; and the thickness of the second film layer 42 ranges from 40 nm to 120 nm.

Specifically, in the embodiments of the present disclosure, the first film layer 41 is made of IGZTO, such that the first film layer 41 has a high mobility, and meanwhile the thickness of the first film layer 41 ranges from 5 nm to 25 nm, which can prevent an excessive increase of photogenerated defects. The second film layer 42 is made of IGZO, and the atomic ratio in IGZO is In:Ga:Zn=1:1:1, and the thickness of the second film layer 42 ranges from 40 nm to 120 nm. In this case, the stability, balanced mobility and resistance of IGZO is utilized. The mobility of IGZO is about 10 cm²/V*s, and this intermedium mobility level can provide certain carriers, so as to compensate for the weak device switching capability caused by the first film layer 41 (i.e., the high mobility layer). Moreover, the intermediate resistance level of IGZO can limit the movement of the carriers of the high mobility layer to a certain extent to control the device to be in a reasonable off-state current level, and the phenomenon that the device overheats and burns due to the high resistance of the device is avoided. In the thin film transistor provided in the embodiments of the present disclosure, the problems of high electric leakage and large current density resulting in burning of the display device can be alleviated.

In some embodiments, as shown in FIG. 2, the second film layer 42 is closer to the gate layer 20 than the first film layer 41 is, that is, the thin film transistor is a top-gate thin film transistor. The first film layer 41 is made of IGZTO or IGO, and the thickness of the first film layer 41 ranges from 10 nm to 20 nm; and the thickness of the second film layer 42 ranges from 10 nm to 50 nm.

Specifically, in the embodiments of the present disclosure, the first film layer 41 is made of IGZTO or IGO, such that the first film layer 41 has a high mobility, and meanwhile the thickness of the first film layer 41 ranges from 10 nm to 20 nm, which can prevent an excessive increase of photogenerated defects. The second film layer 42 is made of IGZO, and the atomic ratio in IGZO is In:Ga:Zn=1:1:1, and the thickness of the second film layer 42 ranges from 10 nm to 50 nm. In this case, the stability, balanced mobility and resistance of IGZO is utilized. The mobility of IGZO is about 10 cm²/V*s, and this intermedium mobility level can provide certain carriers, so as to compensate for the weak device switching capability caused by the first film layer 41 (i.e., the high mobility layer). Moreover, the intermediate resistance level of IGZO can limit the movement of the carriers of the high mobility layer to a certain extent to control the device to be in a reasonable off-state current level, and the phenomenon that the device overheats and burns due to the high resistance of the device is avoided. In the thin film transistor provided in the embodiments of the present disclosure, the problems of high electric leakage and large current density resulting in burning of the display device can be alleviated.

Some embodiments of the present disclosure further provide a method for manufacturing a thin film transistor.

The methods for manufacturing the bottom-gate metal oxide thin film transistor as shown in FIG. 1 and the top-gate metal oxide thin film transistor as shown in FIG. 2 are respectively described in detail below.

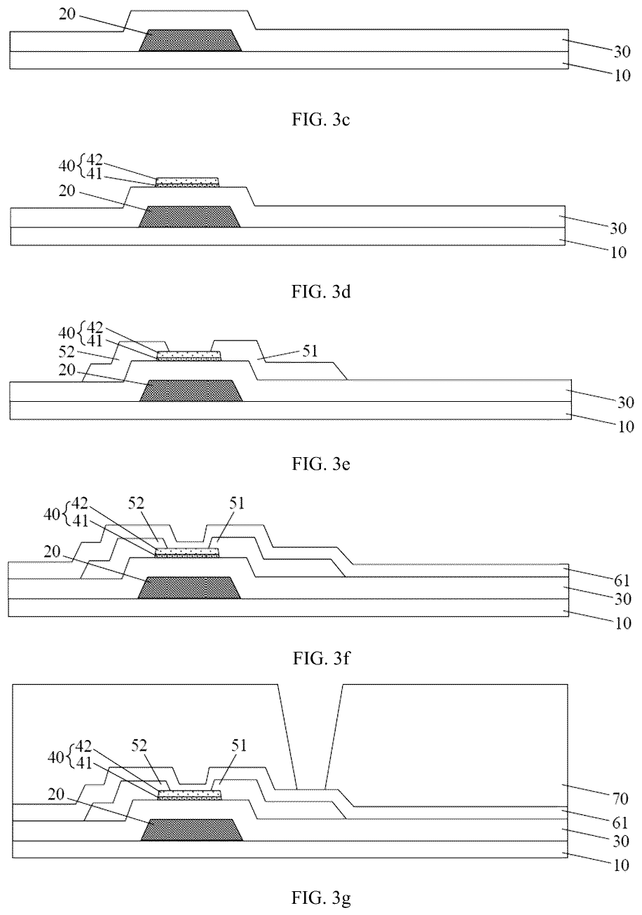

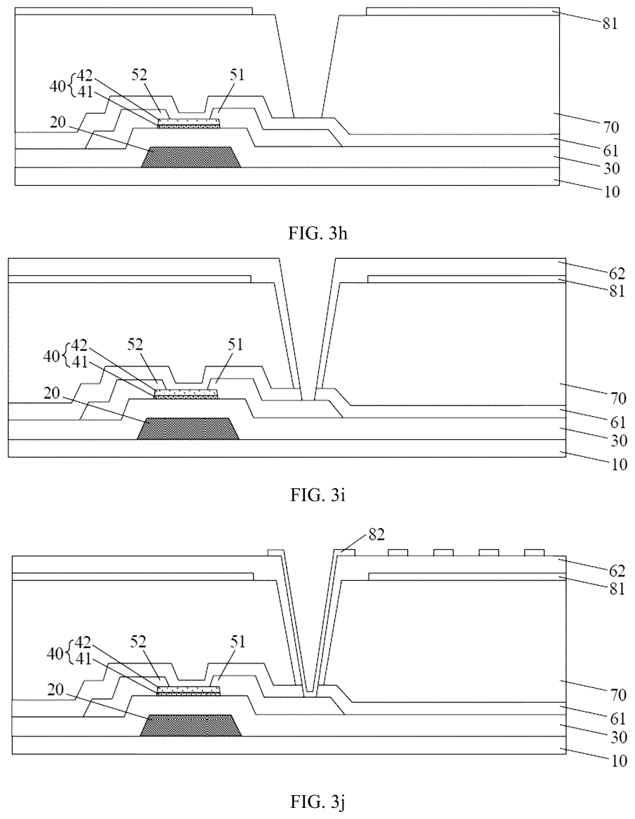

FIG. 3a to FIG. 3j are flow diagrams of a manufacturing process of a bottom-gate metal oxide thin film transistor according to some embodiments of the present disclosure. As shown in FIG. 3a to FIG. 3j, the method for manufacturing the bottom-gate metal oxide thin film transistor as shown in FIG. 1 includes steps S11 to S110, which are specifically as follows.

In S11, abase substrate 10 is provided.

Specifically, as shown in FIG. 3a, the base substrate 10 includes, but is not limited to, a glass substrate. The embodiments of the present disclosure are described by taking that the base substrate 10 is a glass substrate as an example.

In S12, a gate layer 20 is formed.

Specifically, as shown in FIG. 3b, the step of forming the gate layer 20 includes: forming a gate metal layer on the base substrate 10, and patterning the gate metal layer to form the gate layer 20. The method for forming the gate layer 20 includes, but is not limited to, magnetron sputtering. The patterning process includes, but is not limited to, photoetching and imprinting; and etching and transfer imprinting is not limited to wet etching and dry reaction.

In some embodiments, the gate metal layer is patterned through a mask-based process. Specifically, for example, the gate metal layer is coated with photoresist, and the photoresist is exposed by using a corresponding mask. The mask includes a light-transmitting region and a non-light-transmitting region. In the exposure process, the portion of the photoresist corresponding to the light-transmitting region is completely exposed, and the portion of the photoresist corresponding to the non-light-transmitting region is not exposed. Next, the photoresist subjected to exposure is developed to acquire a photoresist pattern, and the photoresist pattern includes a reserved region corresponding to the light-transmitting region and a to-be-removed region corresponding to the non-light-transmitting region. Thereafter, the gate metal layer is etched by using the photoresist pattern. For example, the to-be-removed region of the gate metal layer is completely etched through a wet etching process. Finally, the remaining photoresist is stripped to form the gate layer 20.

Further, in some embodiments, the gate layer 20 includes a buffer layer 12, a main conductive layer, and a top protective layer that are laminated. Specifically, the buffer layer 12 is disposed on a side close to the base substrate 10, and the material of the buffer layer 12 includes, but is not limited to, an alloy of titanium (Ti) and molybdenum (Mo), and the like. The material of the main conductive layer includes, but is not limited to, aluminum (Al), copper (Cu), and the like, and the material of the top protective layer includes, but is not limited to, an alloy of titanium (Ti) and molybdenum (Mo), and the like.

In S13, a gate insulating layer 30 is formed.

Specifically, as shown in FIG. 3c, the step of forming the gate insulating layer 30 includes: forming a first insulating layer on the side of the gate layer 20 away from the base substrate 10, and patterning the first insulating layer to form the gate insulating layer 30. The gate insulating layer 30 covers the gate layer 20.

In some embodiments, the first insulating layer is patterned through a mask-based process. For example, the first insulating layer is coated with photoresist, and the photoresist is exposed by using a corresponding mask. The mask includes a light-transmitting region and a non-light-transmitting region. In the exposure process, the portion of the photoresist corresponding to the light-transmitting region is completely exposed, and the portion of the photoresist corresponding to the non-light-transmitting region is not exposed. Next, the photoresist subjected to exposure is developed to acquire a photoresist pattern, and the photoresist pattern includes a reserved region corresponding to the light-transmitting region and a to-be-removed region corresponding to the non-light-transmitting region. Thereafter, the first insulating layer is etched by using the photoresist pattern. For example, the to-be-removed region of the first insulating layer is completely etched through a dry etching process. Finally, the remaining photoresist is stripped to form the gate insulating layer 30.

In some embodiments, the thickness of the gate insulating layer 30 ranges from 300 nm to 500 nm. Preferably, the gate insulating layer 30 includes silicon oxide, and the thickness of silicon oxide is not less than 100 nm. It should be noted that the material and manufacturing process of the gate insulating layer 30 affects the device characteristics of the thin film transistor significantly. In the embodiments of the present disclosure, the gate insulating layer 30 includes silicon oxide, which can reduce the threshold voltage of the device.

In S14, an active layer 40 is formed.

Specifically, the active layer 40 includes a first film layer 41 and a second film layer 42 sequentially laminated in the direction away from the base substrate 10. As shown in FIG. 3d, the step of forming the active layer 40 includes: forming a first conductive layer and a second conductive layer that are laminated on the side of the gate insulating layer 30 away from the base substrate 10, and patterning the first conductive layer and the second conductive layer to form the first film layer 41 and the second film layer 42. The first film layer 41 and the second film layer 42 form the active layer 40. The material of the first film layer 41 is a high mobility metal oxide, and the mobility of the material of the first film layer 41 is not less than the mobility of the material of the second film layer 42.

It should be noted that the mobility range of the high mobility metal oxide material mentioned in the embodiments of the present disclosure is not less than 20 cm²/V*s. The material of the first film layer 41 includes, but is not limited to, indium gallium oxide (IGO), indium tin zinc oxide (ITZO), indium gallium zinc tin oxide (IGZTO), and the like. Since the mobility of the material of the first film layer 41 is not less than the mobility of the material of the second film layer 42, and the mobility of the material of the first film layer 41 is not less than 20 cm²/V*s, an excessive increase of photogenerated defects can be avoided, and meanwhile the problems of high electric leakage and high current density resulting in burning of the display device can be alleviated.

In some embodiments, the first conductive layer and the second conductive layer are patterned through a mask-based process. Specifically, for example, the side of the first conductive layer and the side of the second conductive layer that are away from the base substrate 10 are coated with photoresist, and the photoresist is exposed by using a corresponding mask. The mask includes a light-transmitting region and a non-light-transmitting region. In the exposure process, the portion of the photoresist corresponding to the light-transmitting region is completely exposed, and the portion of the photoresist corresponding to the non-light-transmitting region is not exposed. Next, the photoresist subjected to exposure is developed to acquire a photoresist pattern, and the photoresist pattern includes a reserved region corresponding to the light-transmitting region and a to-be-removed region corresponding to the non-light-transmitting region. Thereafter, the first conductive layer and the second conductive layer are etched by using the photoresist pattern. For example, the to-be-removed regions of the first conductive layer and the second conductive layer are completely etched through a wet etching process. Finally, the remaining photoresist is stripped to form the first film layer 41 and the second film layer 42.

In some embodiments, the step of forming the active layer 40 further includes depositing a channel. An ITZO layer having a thickness of 30 nm is deposited through magnetron sputtering as the channel of the thin film transistor, and then the channel is annealed to acquire the active layer 40.

In some embodiments, the second film layer 42 is made of IGZO, and the atomic ratio in IGZO is In:Ga:Zn=1:1:1. Specifically, in the embodiments of the present disclosure, the first film layer 41 of the thin film transistor is made of a high mobility metal oxide, the second film layer 42 is made of IGZO, and the atomic ratio in IGZO is In:Ga:Zn=1:1:1. The second film layer 42 is made of IGZO, so as to take advantages of the stability, balanced mobility and resistance of IGZO. The mobility of IGZO is about 10 cm²/V*s, and this intermedium mobility level can provide certain carriers, so as to compensate for the weak device switching capability caused by the first film layer 41 (i.e., the high mobility layer). Moreover, the intermediate resistance level of IGZO can limit the movement of the carriers of the high mobility layer to a certain extent to control the device to be in a reasonable off-state current level, and the phenomenon that the device overheats and burns due to the high resistance of the device is avoided. In the thin film transistor provided in the embodiments of the present disclosure, the problems of high electric leakage and large current density resulting in burning of the display device can be alleviated.

It should be noted that in the embodiments of the present disclosure, the material of the second film layer 42 includes, but is not limited to, IGZO, that is, materials having a property very close to the property of IGZO may also be used to manufacture the second film layer 42, as long as the second film layer 42 can have the same functions as the first film layer 41 with the high mobility, i.e., the functions of alleviating the problems of high electric leakage and large current density resulting in burning of the thin film transistor, and thus increasing the switching capability of the display backplane and prolonging the service life of the product.

Further, in some embodiments, the first film layer 41 is made of IGZTO, and the thickness of the first film layer 41 ranges from 5 nm to 25 nm; and the thickness of the second film layer 42 ranges from 40 nm to 120 nm. Specifically, in the embodiments of the present disclosure, the first film layer 41 is made of IGZTO, such that the first film layer 41 has a relatively high mobility, and meanwhile the thickness of the first film layer 41 ranges from 5 nm to 25 nm, which can prevent an excessive increase of photogenerated defects. The second film layer 42 is made of IGZO, and the atomic ratio in IGZO is In:Ga:Zn=1:1:1, and the thickness of the second film layer 42 ranges from 40 nm to 120 nm. In this case, the stability, balanced mobility and resistance of IGZO is utilized. The mobility of IGZO is about 10 cm²/V*s, and this intermedium mobility level can provide certain carriers, so as to compensate for the weak device switching capability caused by the first film layer 41 (i.e., the high mobility layer). Moreover, the intermediate resistance level of IGZO can limit the movement of the carriers of the high mobility layer to a certain extent to control the device to be in a reasonable off-state current level, and the phenomenon that the device overheats and burns due to the high resistance of the device is avoided. In the thin film transistor provided in the embodiments of the present disclosure, the problems of high electric leakage and large current density resulting in burning of the display device can be alleviated.

In S15, a source layer 51 and a drain layer 52 are formed.

Specifically, as shown in FIG. 3e, the step of forming the source layer 51 and the drain layer 52 includes: depositing the source layer 51 and the drain layer 52 on the side of the active layer 40 away from the base substrate 10. The source layer 51 and the drain layer 52 are disposed on the side of the gate insulating layer 30 away from the base substrate 10, the active layer 40 is disposed on the side of the gate insulating layer 30 away from the base substrate 10, and at least portions of the source layer 51 and drain layer 52 are connected to the active layer 40, that is, the source layer 51 and the drain layer 52 are electrically connected to a source contact region and a drain contact region of the active layer 40, respectively.

In some embodiments, in the process of depositing the source layer 51 and the drain layer 52, the source layer 51 and the drain layer 52 need to be patterned. Since the second film layer 42 of the active layer 40 is made of IGZO, in order to prevent IGZO from being excessively damaged by the etching solution used in the patterning process, preferably, a copper (Cu) laminated layer and a hydrogen peroxide series of etching solutions are used to complete the process.

In S16, a first passivation layer 61 is formed.

Specifically, as shown in FIG. 3f, after the source layer 51 and the drain layer 52 are formed, the first passivation layer 61 is formed on the side of the source layer 51 and the side of the drain layer 52 that are away from the base substrate 10. The first passivation layer 61 is disposed on the side of the source layer 51 and the side of the drain layer 52 that are away from the base substrate 10, and the thickness of the first passivation layer 61 ranges from 300 nm to 400 nm.

The material of the first passivation layer 61 includes silicon oxide, and preferably, the thickness of silicon oxide is not less than 100 nm.

In S17, a planarization layer 70 is formed.

Specifically, as shown in FIG. 3g, after the first passivation layer 61 is formed, the planarization layer 70 is formed on the side of the first passivation layer 61 away from the base substrate 10, such that the surface of the thin film transistor is flat.

In S18, a first electrode layer 81 is formed.

Specifically, as shown in FIG. 3h, after the planarization layer 70 is formed, the first electrode layer 81 is formed on the side of the planarization layer 70 away from the base substrate 10. The first electrode layer 81 is a made of transparent conductive material.

In the embodiments of the present disclosure, the first electrode layer 81 is a common electrode, and the transparent conductive material of the first electrode layer 81 is indium tin oxide (ITO).

In S19, a second passivation layer 62 is formed.

Specifically, as shown in FIG. 3i, after the first electrode layer 81 is formed, the second passivation layer 62 is formed on the side of the first electrode layer 81 away from the base substrate 10. The second passivation layer 62 is provided with an opening which exposes a portion of the source layer 51.

In S110, a second electrode layer 82 is formed.

Specifically, as shown in FIG. 3j, after the second passivation layer 62 is formed, the second electrode layer 82 is formed on the side of the second passivation layer 62 away from the base substrate 10. The second electrode layer 82 is connected to the source layer 51 through a via hole penetrating through the second passivation layer 62.

Specifically, in the embodiments of the present disclosure, the second electrode layer 82 is a pixel electrode. The pixel electrode is connected to the source layer 51 of the thin film transistor, and is in a slit shape to form an electric field with the first electrode layer 81 (the common electrode).

It should be noted that the thin film transistor in the above embodiments of the present disclosure is a back channel etch (BCE) thin film transistor, but the dual active laminated structure in the present disclosure is not limited to the above thin film transistor. For example, the thin film transistor may also be an etch stop layer (ESL) thin film transistor, and the top-gate thin film transistor may be correspondingly changed, which is not particularly limited in the present disclosure.

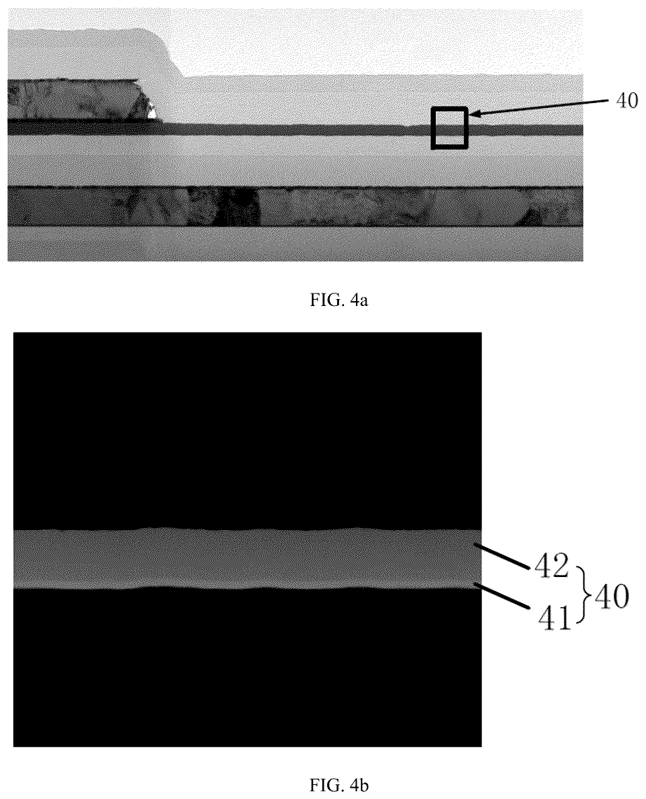

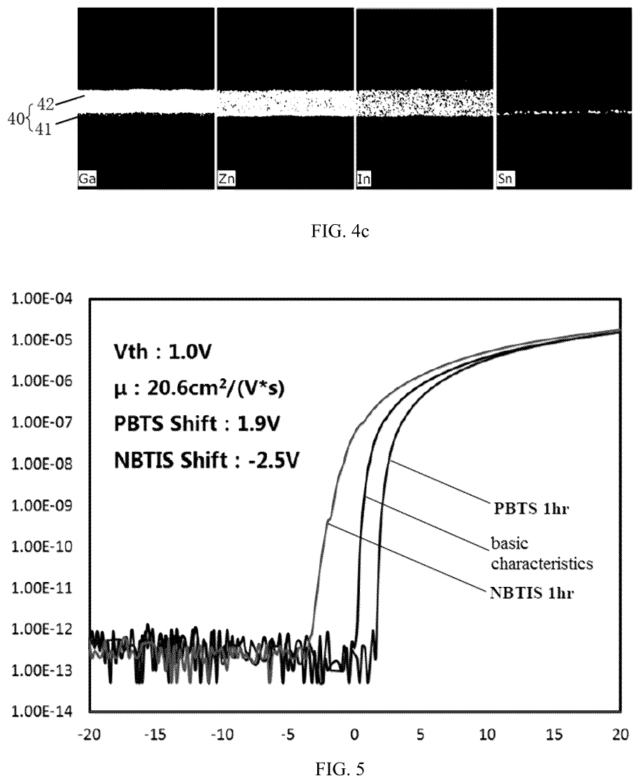

FIG. 4a is a schematic diagram of a transmission electron bright field image for a device section of a bottom-gate metal oxide thin film transistor according to some embodiments of the present disclosure; FIG. 4b is a schematic diagram of a scattered electron dark field image for a bottom-gate metal oxide thin film transistor according to some embodiments of the present disclosure; and FIG. 4c is an energy spectrum diagram of various elements of an active layer of a bottom-gate metal oxide thin film transistor according to some embodiments of the present disclosure. As shown in FIG. 4a, FIG. 4b, and FIG. 4c, the active layer 40 is divided into two layers, which are a first film layer 41 and a second film layer 42, respectively. The first film layer 41 is made of IGZTO, and the second film layer 42 is made of IGZO. As can be clearly seen from FIG. 4c, there is no tin element in the second film layer 42. In actual production, in the first film layer 41, the proportion of the In element content is 15-17 At % (At % represents the atomic percentage), the proportion of the Ga element content is 4-6 At %, the proportion of the Zn element content is 16-20 At %, the proportion of the Sn element content is 2-6 At %, and In:Ga:Zn:Sn is approximately 4:1:4:1.

FIG. 5 is a schematic diagram showing device characteristics of a bottom-gate metal oxide thin film transistor according to some embodiments of the present disclosure. As shown in FIG. 5, Vth represents the threshold voltage of the thin film transistor, and p represents the electron mobility of the thin film transistor. FIG. 5 is merely illustrated by taking an example in which the threshold voltage is 1 V, and the electron mobility is 20.6 cm²/V*s.

In some embodiments, the threshold voltage of the thin film transistor ranges from 1V to 2V.

In some embodiments, the electron mobility of the thin film transistor ranges from 17 cm²/V*s to 24 cm²/V*s.

With continued reference to FIG. 5, the thin film transistor is right shifted by 1.9 V after operating in the positive bias operating state for 1 hour, and the thin film transistor is left shifted by 2.5 V after operating in the negative bias operating state for 1 hour. It can be seen that the bottom-gate metal oxide thin film transistor provided in the embodiments of the present disclosure has a better ageing resistance.

In some embodiments, under the action of the positive bias temperature stress, the positive shift of the threshold voltage of the thin film transistor is less than 3V.

In some embodiments, under the action of the negative bias temperature illumination stress, the negative shift of the threshold voltage of the thin film transistor is less than 4V.

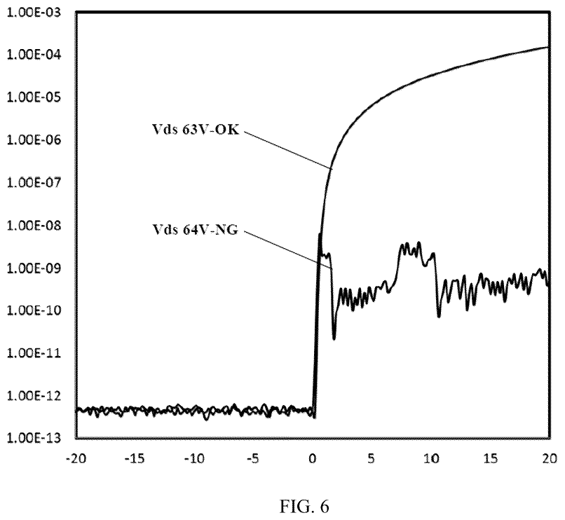

FIG. 6 is a test diagram of withstand voltage Vds capability of a bottom-gate metal oxide thin film transistor according to some embodiments of the present disclosure. As shown in FIG. 6, Vds represents the voltage between the source and the drain of the thin film transistor. It should be noted that when a voltage is applied to the source and the drain of the thin film transistor in the prior art, the withstand voltage Vds is about 35 V. It can be seen that the withstand voltage Vds of the bottom-gate metal oxide thin film transistor provided in the embodiments of the present disclosure is about 63 V, and has been improved significantly, that is, the bottom-gate metal oxide thin film transistor provided in the embodiments of the present disclosure has a stronger withstand voltage Vds capability.

In some embodiments, the withstand voltage between the source and the drain of the thin film transistor is not less than 63 V.

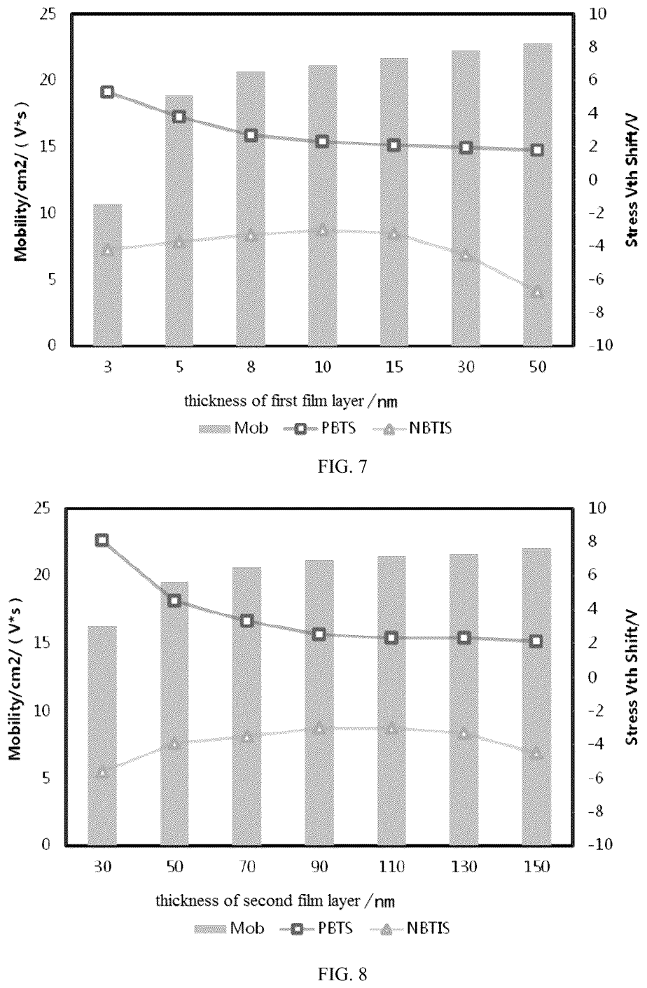

FIG. 7 is a schematic diagram showing a change of the device characteristics with the thickness of the first film layer 41 of the bottom-gate metal oxide thin film transistor according to some embodiments of the present disclosure; and FIG. 8 is a schematic diagram showing a change of the device characteristics with the thickness of the second film layer 42 of the bottom-gate metal oxide thin film transistor according to some embodiments of the present disclosure. As shown in FIG. 7 and FIG. 8, the structure of the active layer 40 and the materials and thicknesses of the first film layer 41 and the second film layer 42 constituting the active layer 40 all affect the device characteristics.

It should be noted that a conducting process needs to be performed on the top-gate metal oxide thin film transistor, that is, a conducting process needs to be performed on the self-aligned active layer 40. The higher the mobility of the material, the poorer the stability of the conducting process, which easily results in the characteristic drift of the whole thin film transistor. That is, the top-gate metal oxide thin film transistor has a poorer process window capability, which weakens the advantages of the metal oxide in applications. In the case that the dual active laminated structure in the embodiments of the present disclosure is applied to a top-gate metal oxide thin film transistor, IGZTO is used as the top layer active material of the second film layer 42, which can not only improve the poorer process window of the single-layer high-mobility material, but also avoid the problem of rapid current decay caused by the poor contact performance of the top layer active layer 40, thereby effectively improving the stability of the conducting process and improving the process window.

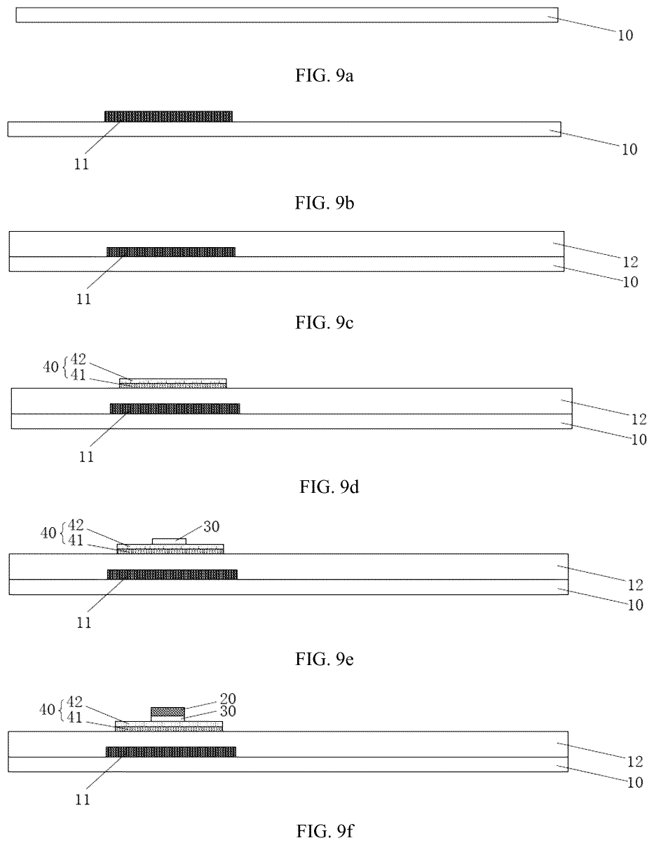

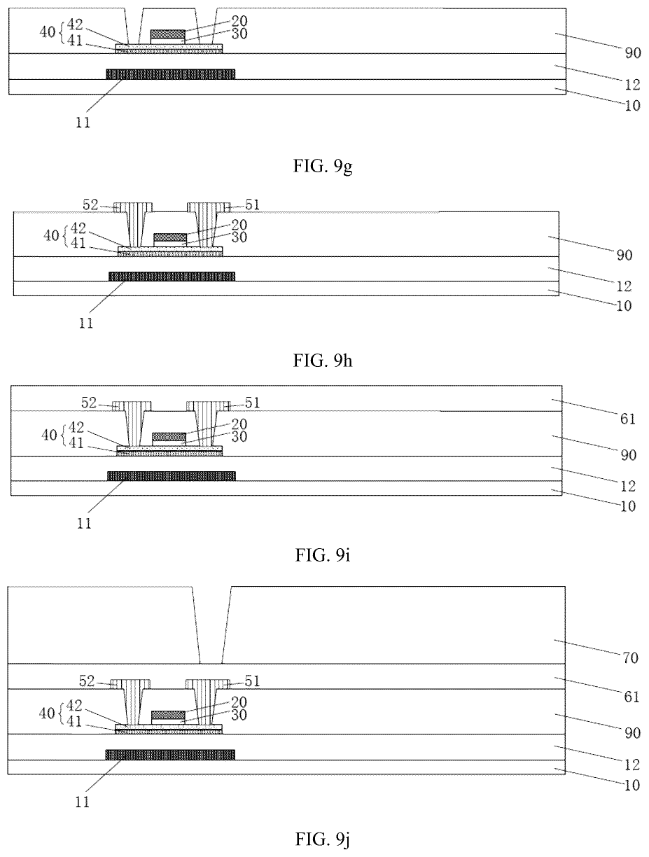

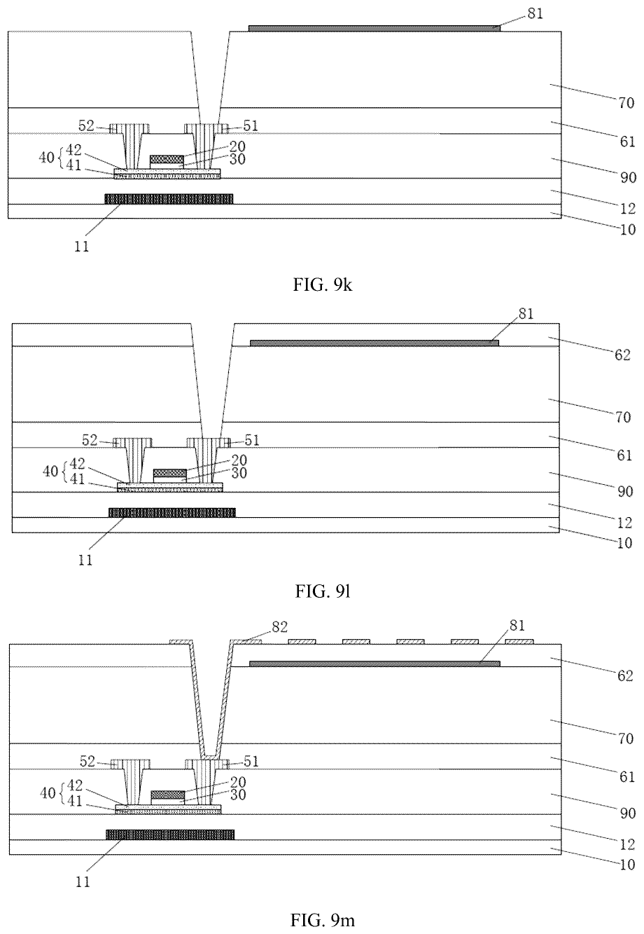

FIG. 9a to FIG. 9m are flow diagrams of a manufacturing process of a top-gate metal oxide thin film transistor according to some embodiments of the present disclosure. As shown in FIG. 9a to FIG. 9m, the method for manufacturing the top-gate metal oxide thin film transistor as shown in FIG. 2 includes steps S21 to S213, which are specifically as follows.

In S21, a base substrate 10 is provided.

Specifically, as shown in FIG. 9a, the base substrate 10 includes, but is not limited to, a glass substrate. The embodiments of the present disclosure are described by taking an example in which the base substrate 10 is a glass substrate.

In S22, a light shielding layer 11 is formed.

Specifically, as shown in FIG. 9b, the step of forming the light shielding layer 11 includes: forming a light shielding metal layer on the base substrate 10, and patterning the light shielding metal layer to form the light shielding layer 11. The method for forming the light shielding layer 11 includes, but is not limited to, magnetron sputtering. The patterning process includes, but is not limited to, photoetching and imprinting; and etching and transfer imprinting is not limited to wet etching and dry reaction.

It should be noted that, since the thin film transistor in the embodiments of the present disclosure is a top-gate thin film transistor, in order to ensure that the active layer 40 of the thin film transistor is not affected by ambient light, the light shielding layer 11 needs to be manufactured. The material of the light shielding layer 11 includes, but is not limited to, a molybdenum (Mo) alloy and a corresponding composite metal structure of copper (Cu) and aluminum (Al).

In S23, a buffer layer 12 is formed.

Specifically, as shown in FIG. 9c, the buffer layer 12 is formed on the side of the light shielding layer 11 away from the base substrate 10.

In some embodiments, the buffer layer 12 is made of silicon oxide, or the buffer layer 12 is a composite film layer of silicon nitride and silicon oxide, and the thickness of the buffer layer 12 ranges from 200 nm to 500 nm.

In S24, an active layer 40 is formed.

Specifically, the active layer 40 includes a first film layer 41 and a second film layer 42 sequentially laminated in the direction away from the base substrate 10. As shown in FIG. 9d, the step of forming the active layer 40 includes: forming a first conductive layer and a second conductive layer laminated on the side of the buffer layer 12 away from the base substrate 10, and patterning the first conductive layer and the second conductive layer to form the first film layer 41 and the second film layer 42. The first film layer 41 and the second film layer 42 form the active layer 40. The first film layer 41 is made of a high mobility metal oxide, and the mobility of the material of the first film layer 41 is not less than the mobility of the material of the second film layer 42.

It should be noted that the mobility range of the high mobility metal oxide material mentioned in the embodiments of the present disclosure is not less than 20 cm²/V*s. The material of the first film layer 41 includes, but is not limited to, indium gallium oxide (IGO), indium tin zinc oxide (ITZO), indium gallium zinc tin oxide (IGZTO), and the like. Since the mobility of the material of the first film layer 41 is not less than the mobility of the material of the second film layer 42, and the mobility of the material of the first film layer 41 is not less than 20 cm²/V*s, an excessive increase of photogenerated defects can be avoided, and meanwhile the problems of high electric leakage and high current density resulting in burning of the display device can be alleviated.

In some embodiments, the first conductive layer and the second conductive layer are patterned through a mask-based process. For example, the side of the first conductive layer and the side of the second conductive layer that are away from the base substrate 10 are coated with photoresist, and the photoresist is exposed by using a corresponding mask. The mask includes a light-transmitting region and a non-light-transmitting region. In the exposure process, the portion of the photoresist corresponding to the light-transmitting region is completely exposed, and the portion of the photoresist corresponding to the non-light-transmitting region is not exposed. Next, the photoresist subjected to exposure is developed to acquire a photoresist pattern, and the photoresist pattern includes a reserved region corresponding to the light-transmitting region and a to-be-removed region corresponding to the non-light-transmitting region. Thereafter, the first conductive layer and the second conductive layer are etched by using the photoresist pattern. For example, the to-be-removed regions of the first conductive layer and the second conductive layer are completely etched through a wet etching process. Finally, the remaining photoresist is stripped to form the first film layer 41 and the second film layer 42.

In some embodiments, the step of forming the active layer 40 further includes depositing a channel. An ITZO layer having a thickness of 30 nm is deposited through magnetron sputtering as the channel of the thin film transistor, and then the channel is annealed to acquire the active layer 40.

In some embodiments, the second film layer 42 is made of IGZO, and the atomic ratio in IGZO is In:Ga:Zn=1:1:1. Specifically, in the embodiments of the present disclosure, the first film layer 41 of the thin film transistor is made of a high mobility metal oxide, the second film layer 42 is made of IGZO, and the atomic ratio in IGZO is In:Ga:Zn=1:1:1. The second film layer 42 is made of IGZO, so as to take advantages of the stability, balanced mobility and resistance of IGZO. The mobility of IGZO is about 10 cm²/V*s, and this intermedium mobility level can provide certain carriers, so as to compensate for the weak device switching capability caused by the first film layer 41 (i.e., the high mobility layer). Moreover, the intermediate resistance level of IGZO can limit the movement of the carriers of the high mobility layer to a certain extent to control the device to be in a reasonable off-state current level, and the phenomenon that the device overheats and burns due to the high resistance of the device is avoided. In the thin film transistor provided in the embodiments of the present disclosure, the problems of high electric leakage and large current density resulting in burning of the display device can be alleviated.

It should be noted that in the embodiments of the present disclosure, the material of the second film layer 42 includes, but is not limited to, IGZO, that is, materials having a property very close to the property of IGZO may also be used to manufacture the second film layer 42, as long as the second film layer 42 can have the same functions as the first film layer 41 with the high mobility, i.e., the functions of alleviating the problems of high electric leakage and large current density resulting in burning of the thin film transistor, and thus increasing the switching capability of the display backplane and prolonging the service life of the product.

Further, in some embodiments, the first film layer 41 is made of IGZTO, and the thickness of the first film layer 41 ranges from 10 nm to 20 nm; and the thickness of the second film layer 42 ranges from 10 nm to 50 nm. Specifically, in the embodiments of the present disclosure, the first film layer 41 is made of IGZTO or IGO, such that the first film layer 41 has a relatively high mobility, and meanwhile the thickness of the first film layer 41 ranges from 10 nm to 20 nm, which can prevent an excessive increase of photogenerated defects. The second film layer 42 is made of IGZO, and the atomic ratio in IGZO is In:Ga:Zn=1:1:1, and the thickness of the second film layer 42 ranges from 10 nm to 50 nm. In this case, the stability, balanced mobility and resistance of IGZO is utilized. The mobility of IGZO is about 10 cm²/V*s, and this intermedium mobility level can provide certain carriers, so as to compensate for the weak device switching capability caused by the first film layer 41 (i.e., the high mobility layer). Moreover, the intermediate resistance level of IGZO can limit the movement of the carriers of the high mobility layer to a certain extent to control the device to be in a reasonable off-state current level, and the phenomenon that the device overheats and burns due to the high resistance of the device is avoided. In the thin film transistor provided in the embodiments of the present disclosure, the problems of high electric leakage and large current density resulting in burning of the display device can be alleviated.

In S25, a gate insulating layer 30 is formed.

Specifically, as shown in FIG. 9e, the gate insulating layer 30 is formed on the side of the active layer 40 away from the base substrate 10. For the specific step of forming the gate insulating layer 30, please refer to step S13 of manufacturing the gate insulating layer 30 of the bottom-gate thin film transistor.

In some embodiments, the thickness of the gate insulating layer 30 ranges from 100 nm to 300 nm. Preferably, the gate insulating layer 30 includes silicon oxide, and the thickness of silicon oxide ranges from 10 nm to 30 nm.

In S26, a gate layer 20 is formed.

Specifically, as shown in FIG. 9f, the gate layer 20 is formed on the side of the gate insulating layer 30 away from the base substrate 10. For the selection of the metal for forming the gate layer 20, please refer to step S12 of manufacturing the gate layer 20 of the bottom-gate thin film transistor.

Specifically, when the gate metal layer is patterned to form the gate layer 20, the gate metal layer is patterned through a mask-based process. Specifically, for example, the gate metal layer is coated with photoresist, and the photoresist is exposed by using a corresponding mask. The mask includes a light-transmitting region and a non-light-transmitting region. In the exposure process, the portion of the photoresist corresponding to the light-transmitting region is completely exposed, and the portion of the photoresist corresponding to the non-light-transmitting region is not exposed. Next, the photoresist subjected to exposure is developed to acquire a photoresist pattern, and the photoresist pattern includes a reserved region corresponding to the light-transmitting region and a to-be-removed region corresponding to the non-light-transmitting region. Thereafter, the gate metal layer is etched by using the photoresist pattern. For example, the to-be-removed region of the gate metal layer is completely etched through a wet etching process. Finally, the remaining photoresist is stripped to form the gate layer 20.

It should be noted that, after photoetching and etching are performed on the gate metal layer, the gate insulating layer 30 is etched by using the gate layer 20 as a mask to expose the active layer 40, and then a conducting process is performed on the active layer 40. Specifically, the conducting process is performed by using plasmas of gases (including a mixed gas) such as helium (He), argon (Ar), hydrogen (H₂), and ammonia (NH₃).

In S27, an interlayer insulating layer 90 is formed.

Specifically, as shown in FIG. 9g, the interlayer insulating layer 90 is deposited on the side of the gate layer 20 away from the base substrate 10. The material of the interlayer insulating layer 90 includes, but is not limited to, silicon oxide, or the interlayer insulating layer 90 is a composite film layer of silicon nitride (Si₃N₄) and silicon oxide. Preferably, the thickness of the interlayer insulating layer 90 ranges from 300 nm to 600 nm.

Specifically, photoetching and etching are performed on the interlayer insulating layer 90 to form a through hole exposing a portion of the active layer 40.

In S28, a source layer 51 and a drain layer 52 are formed.

Specifically, as shown in FIG. 9h, the source layer 51 and the drain layer 52 are deposited on the side of the interlayer insulating layer 90 away from the base substrate 10. The source layer 51 and the drain layer 52 are respectively connected to two opposite sides of the active layer 40 through via holes penetrating through the interlayer insulating layer 90, that is, the source layer 51 and the drain layer 52 are electrically connected to a source contact region and a drain contact region of the active layer 40, respectively.

In S29, a first passivation layer 61 is formed.

Specifically, as shown in FIG. 9i, after the source layer 51 and the drain layer 52 are formed, the first passivation layer 61 is formed on the side of the source layer 51 and the side of the drain layer 52 that are away from the base substrate 10, and an organic material photoetching process is performed on the first passivation layer 61.

In S210, a planarization layer 70 is formed.

Specifically, as shown in FIG. 9j, after the first passivation layer 61 is formed, the planarization layer 70 is formed on the side of the first passivation layer 61 away from the base substrate 10, such that the surface of the thin film transistor is flat.

In S211, a first electrode layer 81 is formed.

Specifically, as shown in FIG. 9k, after the planarization layer 70 is formed, the first electrode layer 81 is formed on the side of the planarization layer 70 away from the base substrate 10. The first electrode layer 81 is made of a transparent conductive material.

In the embodiments of the present disclosure, the first electrode layer 81 is a common electrode, the material of the first electrode layer 81 is a transparent conductive material, and the transparent conductive material of the first electrode layer 81 is indium tin oxide (ITO).

In S212, a second passivation layer 62 is formed.

Specifically, as shown in FIG. 9l, after the first electrode layer 81 is formed, the second passivation layer 62 is formed on the side of the first electrode layer 81 away from the base substrate 10. The second passivation layer 62 is provided with an opening which exposes a portion of the source layer 51.

In S213, a second electrode layer 82 is formed.

Specifically, as shown in FIG. 9m, after the second passivation layer 62 is formed, the second electrode layer 82 is formed on the side of the second passivation layer 62 away from the base substrate 10. The second electrode layer 82 is connected to the source layer 51 through a via hole penetrating through the second passivation layer 62.

Specifically, in the embodiments of the present disclosure, the second electrode layer 82 is a pixel electrode. The pixel electrode is connected to the source layer 51 of the thin film transistor, and is in a slit shape to form an electric field with the first electrode layer 81 (the common electrode).

It should be noted that the manufacturing processes in the embodiments of the present disclosure may be correspondingly adjusted according to different structures of the thin film transistor, as long as the active layer 40 adopts the dual active structure in the embodiments of the present disclosure, the first film layer 41 of the active layer 40 is made of high mobility metal oxide, and the second film layer 42 is made of indium gallium zinc oxide having an atomic ratio of In:Ga:Zn=1:1:1 or materials having similar properties to indium gallium zinc oxide, which is not specifically limited in the present disclosure.

It should be understood that the above embodiments are merely example embodiments used to illustrate the principles of the present disclosure, and the present disclosure is not limited thereto. Various modifications and improvements made by those of ordinary skill in the art without departing from the spirit and substance of the present disclosure shall be within the protection scope of the present disclosure.

1. A thin film transistor, comprising: a base substrate and an active layer disposed on the base substrate, the active layer comprising a first film layer and a second film layer sequentially laminated in a direction away from the base substrate; wherein
a material of the active layer is a metal oxide comprising an indium element and a gallium element, wherein an indium element content in the first film layer is In1, and an indium element content in the second film layer is In2, where 0≤[|In1-In2|/max(In1, In2)]≤0.5; the first film layer and the second film layer are in an amorphous state, and a mobility of a material of the first film layer is greater than a mobility of a material of the second film layer.

2. The thin film transistor according to claim 1, wherein a ratio of a thickness of the second film layer to a thickness of the first film layer ranges from 1 to 10.

3. The thin film transistor according to claim 2, further comprising: a gate layer, and a gate insulating layer disposed between the gate layer and the active layer; wherein
the first film layer is closer to the gate layer than the second film layer is, the thickness of the first film layer ranges from 5 nm to 25 nm, and the thickness of the second film layer ranges from 40 nm to 120 nm.

4. The thin film transistor according to claim 2, further comprising: a gate layer, and a gate insulating layer disposed between the gate layer and the active layer; wherein
the second film layer is closer to the gate layer than the first film layer is, the thickness of the first film layer ranges from 10 nm to 20 nm, and the thickness of the second film layer ranges from 10 nm to 50 nm.

5. The thin film transistor according to claim 2, wherein a gallium element content in the first film layer is Ga1, and a gallium element content in the second film layer is Ga2, where Ga1>Ga2, and 1≤Ga1/Ga2≤4.

6. The thin film transistor according to claim 5, wherein the active layer further comprises a zinc element, a zinc element content in the first film layer is Zn1, and a zinc element content in the second film layer is Zn2, where Zn1>Zn2, and 1≤Zn1/Zn2≤2.

7. The thin film transistor according to claim 5, wherein the active layer further comprises a tin element, a tin element content in the first film layer is T1, and a tin element content in the second film layer is T2, where T1>T2>0.

8. The thin film transistor according to claim 5, wherein a ratio range of the indium element content to the gallium element content in the first film layer is 2≤In1/Ga1≤5.

9. The thin film transistor according to claim 5, wherein a ratio range of the indium element content to the gallium element content in the second film layer is 0≤In2/Ga2≤2.

10-12. (canceled)

13. The thin film transistor according to claim 1, wherein a threshold voltage ranges from 1 V to 2 V.

14. The thin film transistor according to claim 13, wherein an electron mobility ranges from 17 cm²/V*s to 24 cm²/V*s.

15. The thin film transistor according to claim 13, wherein a positive shift of the threshold voltage is less than 3 V under an action of a positive bias temperature stress.

16. The thin film transistor according to claim 13, wherein a negative shift of the threshold voltage is less than 4 V under an action of a negative bias temperature illumination stress.

17. The thin film transistor according to claim 13, wherein a withstand voltage between a source and a drain is not less than 63 V.

18. A method for manufacturing a thin film transistor, comprising:
providing a base substrate; and
forming an active layer; wherein forming the active layer comprises: forming a first film layer and a second film layer that are sequentially laminated along a direction away from the base substrate; wherein a material of the active layer is a metal oxide comprising an indium element and a gallium element, wherein an indium element content in the first film layer is In1, and an indium element content in the second film layer is In2, where 0≤[|In1-In2|/max(In1, In2)]≤0.5; the first film layer and the second film layer are in an amorphous state, and a mobility of a material of the first film layer is greater than a mobility of a material of the second film layer.

19. The method according to claim 18, wherein the material of the second film layer is indium gallium zinc oxide, and an atomic ratio in indium gallium zinc oxide is In:Ga:Zn=1:1:1.

20. The method according to claim 19, further comprising:
forming a gate layer and a gate insulating layer sequentially on the base substrate prior to forming the active layer; and
forming a source layer and a drain layer upon forming the active layer, wherein the source layer and the drain layer are electrically connected to a source contact region and a drain contact region of the active layer, respectively.

21. (canceled)

22. The method according to claim 19, further comprising:
forming a light shielding layer and a buffer layer sequentially on the base substrate prior to forming the active layer; and
forming a gate layer, a gate insulating layer, an interlayer insulating layer, a source layer and a drain layer upon forming the active layer, wherein the source layer and the drain layer are electrically connected to a source contact region and a drain contact region of the active layer, respectively.

23. (canceled)

24. A method for manufacturing a display substrate, wherein the display substrate comprises: a thin film transistor manufactured by:
providing a base substrate; and
forming an active layer; wherein forming the active layer comprises: forming a first film layer and a second film layer that are sequentially laminated along a direction away from the base substrate; wherein a material of the active layer is a metal oxide comprising an indium element and a gallium element, wherein an indium element content in the first film layer is In1, and an indium element content in the second film layer is In2, where 0≤[|In1-In2|/max(In1, In2)]≤0.5; the first film layer and the second film layer are in an amorphous state, and a mobility of a material of the first film layer is greater than a mobility of a material of the second film layer.

25. The method according to claim 24, further comprising:
forming a first passivation layer, wherein the first passivation layer is disposed on a side of the source layer and a side of the drain layer that are away from the base substrate;
forming a planarization layer, wherein the planarization layer is disposed on a side of the first passivation layer away from the base substrate;
forming a first electrode layer, wherein the first electrode layer is disposed on a side of the planarization layer away from the base substrate, and a material of the first electrode layer is a transparent conductive material;
forming a second passivation layer, wherein the second passivation layer is disposed on a side of the first electrode layer away from the base substrate;
forming a second electrode layer, wherein the second electrode layer is disposed on a side of the second passivation layer away from the base substrate, and the second electrode layer is connected to the source layer through a via hole penetrating through the second passivation layer.
